(19) United States
(12) Patent Application Publication
(10) Pub. No.: US 2011/0193243 A1
(43) Pub. Date: Aug. 11, 2011

(54) Unique Package Structure

(75) Inventors: Piyush Gupta, San Diego, CA (US); Shantanu Kalchuri, San Diego, CA (US)

(73) Assignee: QUALCOMM Incorporated, San Diego, CA (US)

(21) Appl. No.: 12/703,403

(22) Filed: Feb. 10, 2010

(51) Int. Cl. H01L 23/28; H01L 21/60

(52) U.S. Cl. 257/778; 438/108; 257/E23.116; 257/E23.08; 257/E21.511

(57) ABSTRACT

A system in a package comprising a flip chip semiconductor die on a package substrate, a spacer on the package substrate, and a wire bond semiconductor die supported by the spacer and the flip chip semiconductor die.

### TECHNICAL FIELD

The present disclosure generally relates to packaged semiconductor dies. More specifically, the present disclosure relates to improved semiconductor die packages wherein a first die is placed upon a second die and a spacer.

### BACKGROUND

Conventionally, chip packages include multiple semiconductor dies. Some chip packages include a Radio Frequency (RF) die of a small form factor and a larger digital die. One prior art chip package is shown in FIG. 1. The chip package 100 includes an RF die 101 and a digital die 102. In FIG. 1, the larger digital die 102 is structured as a flip chip Ball Grid Array (BGA), and the RF die 101 uses wire bond structures. The chip package 100 uses the capillary underfill 103, which increases the production cost and results in a larger overall package, since the capillary underfill 103 extends outwardly somewhat from the length and width dimensions of the larger digital die 102. Furthermore, using wire bonds with the stacked RF die 101 tends to degrade RF performance because the inductance of the wire is very high and causes nonlinearities in the RF die 101. Another approach, not shown herein, implements both of the dies 101 and 102 with wire bond structures. Such approach also suffers from decreased RF performance.

Yet another approach, also not shown herein, places both dies 101 and 102 side-by-side in the package. However, the side-by-side approach comes at a cost of increased package size, even more so than for the embodiment shown in FIG. 1.

### BRIEF SUMMARY

Various embodiments of the present disclosure include a system in a package that has a flip chip semiconductor die on a package substrate, a spacer on the package substrate, and a wire bond semiconductor die supported by the spacer and the flip chip semiconductor die.

According to another embodiment, a chip package includes a flip chip semiconductor die on a package substrate, means for dissipating heat on the package substrate, and a wire bond semiconductor die supported by the heat dissipation means and the flip chip semiconductor die.

According to another embodiment of the disclosure, a method for assembling a system in a package includes disposing a flip chip semiconductor die on a package substrate, disposing a flip chip spacer on the package substrate, and disposing a wire bond semiconductor die onto the spacer and the flip chip semiconductor die.

According to yet another embodiment of the disclosure, a system in a package comprises a flip chip semiconductor die on a package substrate, means for providing mechanical support disposed upon the package substrate, and a wire bond semiconductor die disposed upon the mechanical supporting means and the flip chip semiconductor die.

The foregoing has outlined rather broadly the features and technical advantages of the present disclosure in order that the detailed description that follows may be better understood. Additional features and advantages will be described hereinafter which form the subject of the claims of the disclosure. It should be appreciated by those skilled in the art that the conception and specific embodiments disclosed may be readily utilized as a basis for modifying or designing other structures for carrying out the same purposes of the present disclosure. It should also be realized by those skilled in the art that such equivalent constructions do not depart from the technology of the disclosure as set forth in the appended claims. The novel features which are believed to be characteristic of the disclosure, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is an illustration of a prior art chip package.

FIG. 2 is a block diagram showing an exemplary wireless communication system in which an embodiment of the disclosure may be advantageously employed.

FIGS. 3A and 3B are top view and side view block diagrams, respectively of an exemplary chip package, adapted according to one embodiment of the disclosure.

FIG. 4 is an illustration of an exemplary chip package, adapted according to one embodiment of the disclosure.

FIG. 5 is an illustration of an exemplary process, adapted according to one embodiment of the disclosure, for making a chip package.

### DETAILED DESCRIPTION

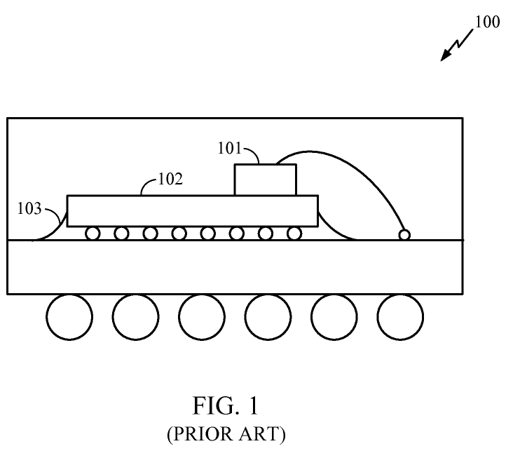

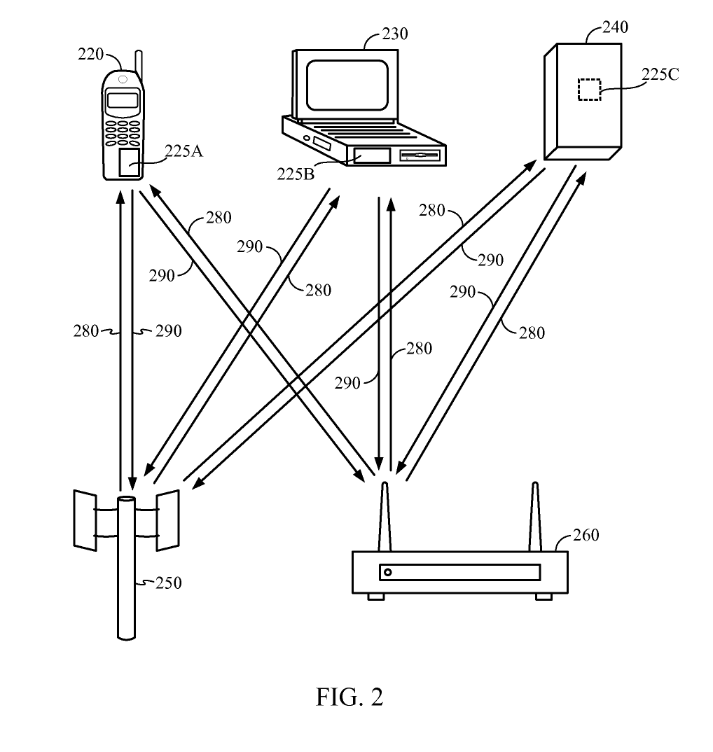

FIG. 2 shows an exemplary wireless communication system 200 in which an embodiment of the disclosure may be advantageously employed. For purposes of illustration, FIG. 1 shows three remote units 220, 230, and 240 and two base stations 250 and 260. It will be recognized that wireless communication systems may have many more remote units and base stations. Remote units 220, 230, and 240 include improved semiconductor die packages 225A, 225B, and 225C, respectively, which are embodiments as discussed further below. FIG. 2 shows forward link signals 280 from the base stations 250 and 260 and the remote units 220, 230, and 240 and reverse link signals 290 from the remote units 220, 230, and 240 to base stations 250 and 260.

In FIG. 2, remote unit 220 is shown as a mobile telephone, remote unit 230 is shown as a portable computer, and remote unit 240 is shown as a computer in a wireless local loop system. For example, the remote units may be mobile phones, hand-held personal communication systems (PCS) units, portable data units such as personal data assistants, GPS enabled devices, navigation devices, set top boxes, media players, such as music players, video players, and entertainment units, fixed location data units such as meter reading equipment, or any other device that stores or retrieves data or computer instructions, or any combination thereof. Although FIG. 2 illustrates remote units according to the teachings of the disclosure, the disclosure is not limited to these exemplary illustrated units. The disclosure may be suitably employed in any device which includes a semiconductor die package.

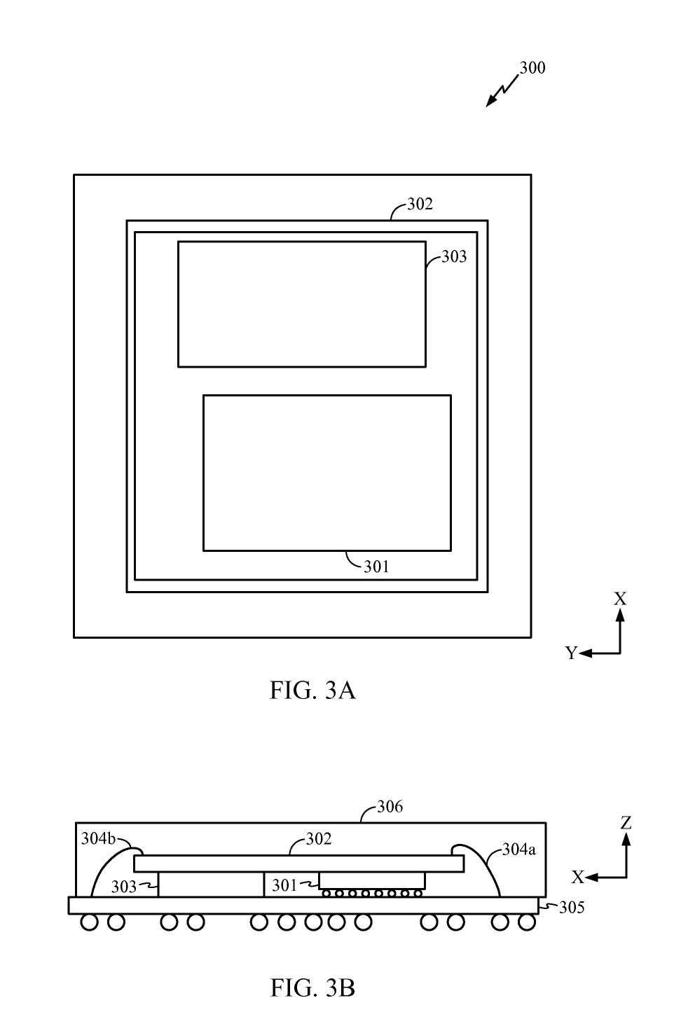

FIGS. 3A and 3B are top view and side view block diagrams, respectively, of the exemplary chip package 300, adapted according to one embodiment of the disclosure. FIG. 3A shows a top-down view of the chip package 300. FIG. 3B shows a side view of the chip package 300.

The chip package 300 includes an RF die 301, implemented as a flip-chip BGA, a digital die 302 with wire bonds 304, and a spacer 303 disposed upon a package substrate 305. In the chip package 300, the digital die 302 is disposed upon, and supported by, the spacer 303 and the RF chip 301. Since the RF die 301 is implemented as a flip chip BGA, it does not suffer the decreased RF performance of the embodiment shown in FIG. 1.

Furthermore the chip package 300, in some embodiments, can forego use of a capillary underfill in favor the Mold-Only Underfill (MUF) 306 because the mold-only underfill 306 encases and adequately supports both chips 301 and 302. Typically, the mold-only underfill process is limited for use with small dies and high pitch dies. In FIG. 3, the smaller die (301) is a flip chip die with a larger pitch so that it is readily adapted for use with a mold-only underfill process. By contrast, in FIG. 1, the larger digital die 102 is a flip chip die with a small pitch, making a mold-only underfill process less desirable than the capillary underfill 103. As is known in the art, underfill adheres a die to its contact on a package to protect against the effects of thermal expansion and mechanical shock. The mold-only underfill 306 is underfill that encapsulates the entire package, rather than a single die. The embodiment shown in FIGS. 3A and 3B takes advantage of the mold-only underfill 306 as an underfill for the RF die 301, thereby eliminating steps taken by the prior art of FIG. 1 to apply capillary underfill. It should be noted, though, that various embodiments do not exclude the use of capillary underfill.

The RF die 301 is placed somewhat off-center of the package 300 so that the signals therefrom can be routed easily to the edge of the package 300. However, were the spacer 303 to be eliminated from the package 300, the amount of overhang of the digital die 302 would be excessive. Thus, in one aspect, the spacer 303 provides mechanical support for the digital die 302 while allowing the RF die 301 to be placed off-center. Furthermore, in the embodiment of FIGS. 3A and 3B, the mold-only underfill 306 is made of epoxy with particulates, such as silica particles. The spacer 303, in this embodiment, is made of silicon which conducts heat more effectively than the epoxy compound of the mold-only underfill 306. Thus, the spacer 303, by virtue of its material, provides a path for heat from the digital die 302 to be transferred to the substrate 305 thereby providing heat dissipation. In another embodiment, the spacer 303 includes thermally conductive materials, such as copper, in through vias to further increase the heat transfer capabilities of the spacer 303.

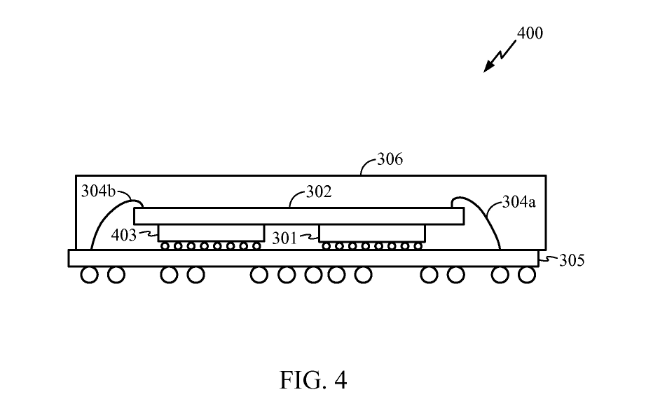

FIG. 4 is an illustration of an exemplary chip package 400, adapted according to one embodiment of the disclosure. In many embodiments it is possible to use a thin-film deposition process to implement passive devices on one or more spacers. Passive devices include, for example, inductors, capacitors, and resistors. The chip package 400 includes a spacer 403, implemented as a flip chip BGA, with passive devices integrated thereon (not shown). The passive devices are in electrical communication with other components in the chip package 400 by virtue of the flip chip contacts of the spacer 403, and the spacer 403 provides mechanical support and heat transfer as described above with respect to FIGS. 3A and 3B. Implementing passive devices upon a spacer, such as the spacer 403, may in some embodiments save space by moving otherwise externally-placed passive devices within the footprint of the spacer.

The embodiments shown above include one wire bond die, one spacer, and one smaller flip chip die, but embodiments are not so limited. For instance, chip packages may include two or more of each. Thus, some embodiments may include two or more structures that each include a wire bond die disposed on top of a spacer and a flip chip die. Moreover, other embodiments may include structures that each include a wire bond die disposed upon one or more spacers and one or more flip chip dies. Furthermore, while specific materials have been mentioned above, it is noted that other suitable materials now known or later developed for substrates, dies, spacers and underfills may be incorporated into various embodiments of the disclosure.

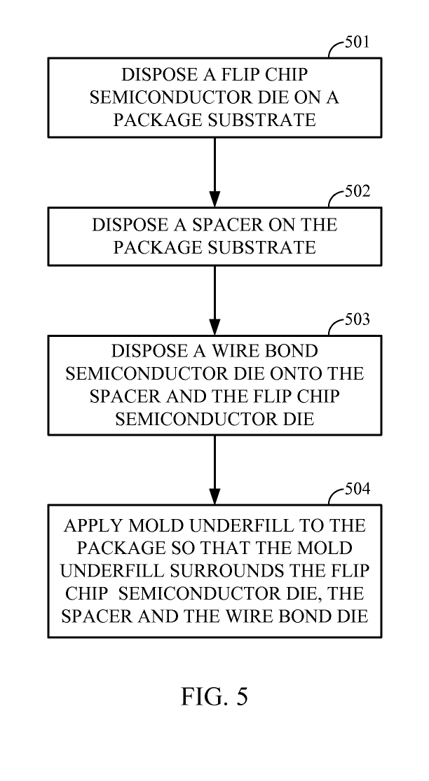

FIG. 5 is an illustration of the exemplary process 500, adapted according to one embodiment of the disclosure, for making a chip package. Process 500 may be performed, for example, by one or more machines and computer-controlled processes in a fabrication facility.

In the block 501, a flip chip semiconductor die is disposed on a package substrate. In some embodiments the flip chip semiconductor die includes an RF die. The block 501 can include any of a variety of suitable techniques for disposing the semiconductor die, including but not limited to, aligning solder bumps on the semiconductor die with contacts on the package substrate and flowing the solder material after alignment.

In the block 502, a spacer is disposed upon the package substrate. In embodiments wherein the spacer has passive devices integrated thereon, the spacer may be disposed upon the package substrate in a manner similar to techniques used to dispose the die on the package substrate in block 501. In embodiments wherein the spacer is a dummy spacer, it may be disposed upon the package substrate by, for example, use of epoxy die attach material.

In the block 503, a wire bond semiconductor die is disposed onto the spacer and the flip chip semiconductor die by, e.g., use of epoxy die attach material. Examples of types of digital dies include, but are not limited to, Digital Signal Processors (DSPs), Application Specific Integrated Circuits (ASICs), general purpose processors, and the like. The block 503 in some embodiments also includes making the wire bond connections between the contacts of the wire bond semiconductor die and the package substrate.

In the block 504, mold-only underfill is applied to the package so that the mold underfill surrounds the flip chip semiconductor die, the spacer and the wire bond die, as is shown in FIGS. 3A, 3B, and 4. Once the package itself is completed, it is ready to be installed in one or more devices, such as a cell phone, a navigation device, a media player, a personal digital assistant (PDA), a computer, or the like.

The process 500 is shown as a series of discrete processes, but embodiments are not necessarily limited to the process shown in FIG. 5. Some embodiments may add, omit, rearrange, or modify one or more blocks in process 500. For instance, blocks 501 and 502 may be transposed or performed at the same time. Furthermore, in some embodiments, capillary underfill may be applied to the flip chip semiconductor die, whereas it may be omitted in favor of the mold-only underfill in other embodiments. Moreover, various embodiments may include integrating passive devices upon the spacer by, for example, thin film processing.

Various embodiments include advantages over prior art chip packages. For instance, some embodiments increase RF performance by implementing an RF chip as a flip chip BGA, rather than as a wire bond structure, without increasing the size of the package as a whole. In fact, some embodiments utilize a smaller package than that shown in FIG. 1 by utilizing vertical stacking and eliminating capillary underfill. Additionally, some embodiments take advantage of the heat conducting properties of silicon (or other) material in spacers by using spacers for heat dissipation of a wire bond die.

Although the present disclosure and its advantages have been described in detail, it should be understood that various changes, substitutions and alterations can be made herein without departing from the technology of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A system in a package comprising:
a flip chip semiconductor die on a package substrate;
a spacer on the package substrate; and
a wire bond semiconductor die supported by the spacer and the flip chip semiconductor die.

2. The system of claim 1 further comprising a mold underfill surrounding the flip chip semiconductor die, the spacer and the wire bond semiconductor die.

3. The system of claim 2 in which the mold underfill comprises an epoxy material.

4. The system of claim 1 further comprising a capillary underfill surrounding at least a portion of the flip chip semiconductor die.

5. The system of claim 1 in which the spacer comprises an integrated passive device.

6. The system of claim 1 in which the system in a package is disposed in an item selected from a group consisting of:
a handheld device; and
a personal computer.

7. The system of claim 1 in which the flip chip semiconductor die comprises a Radio Frequency (RF) die.

8. The system of claim 1 in which the wire bond semiconductor die comprises a digital die.

9. The system of claim 1 in which the spacer and wire bond semiconductor die are thermally coupled.

10. The system of claim 9 in which the spacer comprises a material that has a greater thermal conductivity than a mold underfill that is disposed on the package substrate.

11. A method for assembling a system in a package, comprising:
disposing a flip chip semiconductor die on a package substrate;
disposing a spacer on the package substrate; and
disposing a wire bond semiconductor die onto the spacer and the flip chip semiconductor die.

12. The method of claim 11 further comprising:
applying mold underfill to the package so that the mold underfill surrounds the flip chip semiconductor die, the spacer and the wire bond semiconductor die.

13. The method of claim 11 further comprising:
integrating at least one passive devices on the spacer.

14. The method of claim 11 further comprising installing the system in a package in a device selected from a group consisting of:
a media player;
a navigation device;
a communication device;
a personal digital assistant (PDA); and
a computer.

15. A system in a package, comprising:
a flip chip semiconductor die on a package substrate;
means for dissipating heat on the package substrate; and
a wire bond semiconductor die supported by the heat dissipation means and the flip chip semiconductor die.

16. The system of claim 15 further comprising a mold underfill surrounding the flip chip semiconductor die, the heat dissipation means and the wire bond semiconductor die.

17. The system of claim 15 comprising no capillary underfill surrounding the flip chip semiconductor die.

18. A system in a package, comprising:
a flip chip semiconductor die on a package substrate;
means, disposed upon the package substrate, for providing mechanical support; and
a wire bond semiconductor die disposed upon the mechanical supporting means and the flip chip semiconductor die.

19. The system of claim 18 in which the mechanical supporting means comprises an integrated passive device and a ball grid array.

20. The system of claim 18 in which the flip chip semiconductor die comprises a Radio Frequency (RF) die.
